(19) United States
(12) Patent Application Publication
(10) Pub. No.: US 2024/0121983 A1
(43) Pub. Date: Apr. 11, 2024

(54) THIN FILM TRANSISTOR, AND TRANSISTOR ARRAY SUBSTRATE

(71) Applicant: Samsung Display Co., LTD., Yongin-si (KR)

(72) Inventors: So Young KOO, Yongin-si (KR); Myoung Hwa KIM, Yongin-si (KR); Eok Su KIM, Yongin-si (KR); Hyung Jun Kim, Yongin-si (KR)

(21) Appl. No.: 18/368,461

(22) Filed: Sep. 14, 2023

(30) Foreign Application Priority Data
Oct. 6, 2022 (KR) 10-2022-0128198
Feb. 8, 2023 (KR) 10-2023-0016817

(51) Int. Cl. H10K 59/121; H10K 59/12; H10K 59/126; H10K 59/131

(52) U.S. Cl. CPC H10K 59/1213; H10K 59/1201; H10K 59/1216; H10K 59/126; H10K 59/131

(57) ABSTRACT

A thin film transistor includes a substrate; an active layer including a channel area, a first conductive area, and a second conductive area; a gate insulating layer on a portion of the active layer; a first through hole penetrating through a portion of the first conductive area; a second through hole penetrating through a portion of the second conductive area; a gate electrode overlapping the channel area of the active layer; a first electrode electrically connected to the first conductive area; and a second electrode electrically connected to the second conductive area. One side of the first electrode adjacent to the first through hole is parallel to the one side of the first through hole, the first electrode including protrusion parts at both ends thereof and a groove part concavely recessed from the gate electrode.

### CROSS-REFERENCE TO RELATED APPLICATION

This application claims priority to and the benefit of Korean Patent Application No. 10-2022-0128198 filed on Oct. 6, 2022, in the Korean Intellectual Property Office and from Korean Patent Application No. 10-2023-0016817 filed on Feb. 8, 2023, in the Korean Intellectual Property Office, the entire contents of all of which are incorporated by reference herein.

### BACKGROUND

### 1. Field

The present disclosure relates to a thin film transistor and a transistor array substrate including the same.

### 2. Description of the Related Art

As the information society develops, the demand for display devices for displaying images has increased and diversified. For example, display devices have been applied to various electronic devices such as smartphones, digital cameras, laptop computers, navigation devices, and smart televisions.

The display device may include a display panel emitting light for displaying an image, and a driver supplying signals or power for driving the display panel.

The display panel may include a display area in which the light for displaying the image is emitted, and may include a polarizing member or a light emitting member disposed in the display area.

Sub-pixels emitting light of each luminance and color may be arranged in the display area.

In addition, the display panel may include a transistor array substrate including a substrate and a circuit layer including pixel drivers disposed on the substrate and each corresponding to sub-pixels. With such a transistor array substrate, light of each luminance and color may be emitted from the sub-pixels of the display area.

Each of the pixel drivers of the transistor array substrate may include at least one thin film transistor (TFT).

The thin film transistor includes a gate electrode, a first electrode, a second electrode, and an active layer. Such a thin film transistor may be a switching element in which a current flows through a channel area of the active layer when a voltage difference between the gate electrode and the first electrode becomes a threshold value or more by a driving signal transferred to the gate electrode.

### SUMMARY

When the transistor array substrate including the thin film transistor is manufactured, as the number of mask processes increases, a manufacturing cost may increase and a yield may decrease.

However, when the number of mask processes is decreased, components of the thin film transistor may not be provided by mask processes suitable for respective characteristics, and thus, it is likely that the components of the thin film transistor will not be provided as designed, such that reliability and uniformity of current characteristics of the thin film transistor may be deteriorated.

Aspects and features of embodiments of the present disclosure provide a thin film transistor capable of being provided by a relatively small number of mask processes, having improved current characteristics, and a transistor array substrate including the same.

According to one or more embodiments, a thin film transistor includes a substrate; an active layer on the substrate and including a channel area, a first conductive area connected to one side of the channel area, and a second conductive area connected to an other side of the channel area; a gate insulating layer on a portion of the active layer; a first through hole penetrating through a portion of the first conductive area; a second through hole penetrating through a portion of the second conductive area; a gate electrode in an electrode conductive layer on the gate insulating layer and overlapping the channel area of the active layer; a first electrode in the electrode conductive layer, adjacent to one side of the first through hole, and electrically connected to the first conductive area; and a second electrode in the electrode conductive layer, adjacent to one side of the second through hole, and electrically connected to the second conductive area. One side of the first electrode adjacent to the first through hole is parallel to the one side of the first through hole, the first electrode including protrusion parts at both ends thereof and a groove part concavely recessed from the gate electrode as compared with the protrusion parts.

The first conductive area corresponds to a first electrode connection hole penetrating through the gate insulating layer. The second conductive area corresponds to a second electrode connection hole penetrating through the gate insulating layer. The first electrode extends to the first conductive area and in contact with a first contact area of the first conductive area. The second electrode extends to the second conductive area and in contact with a second contact area of the second conductive area.

A length of a first pass area between the one side of the first through hole and the first contact area in the first conductive area is greater than a width of the one side of the first through hole.

One side of the second electrode adjacent to the second through hole is parallel to the one side of the second through hole, is symmetrical to the first electrode with respect to the gate electrode, the second electrode including protrusion parts and a groove part. A length of a second pass area between the one side of the second through hole and the second contact area in the second conductive area is greater than a width of the one side of the second through hole.

The first conductive area includes a first main area between the channel area and the first pass area. The second conductive area includes a second main area located between the channel area and the second pass area.

In a first direction in which the first electrode and the gate electrode face each other, a maximum width of the first contact area is greater than a width of the groove part.

In the first direction, a difference between the maximum width of the first contact area and the width of the groove part is 0.5 μm or more.

In a second direction crossing the first direction, a width of the first conductive area is greater than a width of the first through hole. One side of an edge of the first through hole in the first direction is in contact with the first pass area, and the other side of the edge of the first through hole in the first direction and both sides of the edge of the first through hole in the second direction are in contact with the first main area.

A width of the groove part in the second direction is equal to or less than ½ of a width of the first through hole in the second direction.

The width of the groove part in the second direction is 1 μm or more.

The length of the first pass area corresponds to the width of the first through hole in the second direction and the width of the groove part in the first direction.

The one side of the first electrode further includes a middle protrusion part between two or more groove parts.

A width of the middle protrusion part in the second direction is 1 μm or more.

The groove part has a curved arc shape. The length of the first pass area corresponds to the width of the first through hole in the second direction and an arc length of the groove part.

The active layer further includes a first non-active area connected to the first contact area of the first conductive area and covered with the gate insulating layer; and a second non-active area connected to the second contact area of the second conductive area and covered with the gate insulating layer.

According to one or more embodiments, a transistor array substrate includes a substrate including a display area in which sub-pixels are arranged; and a circuit layer on the substrate and including pixel drivers, each of the pixel drivers corresponding to a sub-pixel of the sub-pixels. Each of the pixel drivers includes at least one thin film transistor. The thin film transistor of the circuit layer includes an active layer on the substrate and including a channel area, a first conductive area connected to one side of the channel area, and a second conductive area connected to an other side of the channel area; a gate insulating layer on a portion of the active layer; a first through hole penetrating through a portion of the first conductive area; a second through hole penetrating through a portion of the second conductive area; a gate electrode in an electrode conductive layer on the gate insulating layer and overlapping the channel area of the active layer; a first electrode in the electrode conductive layer, adjacent to one side of the first through hole, and electrically connected to the first conductive area; and a second electrode in the electrode conductive layer, adjacent to one side of the second through hole, and electrically connected to the second conductive area. One side of the first electrode adjacent to the first through hole is parallel to the one side of the first through hole, the first electrode including protrusion parts at both ends thereof and a groove part concavely recessed from the gate electrode as compared with the protrusion parts.

The first conductive area corresponds to a first electrode connection hole penetrating through the gate insulating layer. The second conductive area corresponds to a second electrode connection hole penetrating through the gate insulating layer. The first electrode extends to the first conductive area and contacts a first contact area of the first conductive area. The second electrode extends to the second conductive area and contacts a second contact area of the second conductive area. A length of a first pass area between the one side of the first through hole and the first contact area in the first conductive area is greater than a width of the one side of the first through hole. One side of the second electrode adjacent to the second through hole is parallel to the one side of the second through hole, is symmetrical to the first electrode with respect to the gate electrode, and includes protrusion parts and a groove part. A length of a second pass area between the one side of the second through hole and the second contact area in the second conductive area is greater than a width of the one side of the second through hole.

The first conductive area includes a first main area between the channel area and the first pass area. In a first direction in which the first electrode and the gate electrode face each other, a maximum width of the first contact area is greater than a width of the groove part. In a second direction crossing the first direction, a width of the first conductive area is greater than a width of the first through hole. One side of an edge of the first through hole in the first direction is in contact with the first pass area, and the other side of the edge of the first through hole in the first direction and both sides of the edge of the first through hole in the second direction are in contact with the first main area.

The length of the first pass area corresponds to the width of the first through hole in the second direction and the width of the groove part in the first direction.

The active layer further includes a first non-active area connected to the first contact area of the first conductive area and covered with the gate insulating layer; and a second non-active area connected to the second contact area of the second conductive area and covered with the gate insulating layer.

The transistor array substrate further includes a light emitting element layer on a via layer of the circuit layer. The light emitting element layer includes light emitting elements electrically connected to the pixel drivers through anode contact holes penetrating through the via layer and an interlayer insulating layer. The circuit layer further includes scan gate lines to transfer scan signals to the pixel drivers; data lines to transfer data signals to the pixel drivers; and initialization voltage lines to transfer initialization voltages to the pixel drivers. A pixel driver from among the pixel drivers includes a first thin film transistor connected to a light-emitting element from among the light emitting elements in series between a first power line and a second power line, the first and second power lines to transfer a first power and a second power for driving the light emitting elements; a second thin film transistor electrically connected between the data line and a gate electrode of the first thin film transistor and is configured to turn on based on a scan signal of the scan gate line; a pixel capacitor electrically connected to a first node between the gate electrode of the first thin film transistor and the second thin film transistor and a second node between the first thin film transistor and the light emitting element; and a third thin film transistor electrically connected between the initialization voltage line and the second node and is configured to turn on based on an initialization control signal of an initialization gate line.

The circuit layer further includes a light blocking electrode in a light blocking conductive layer on the substrate and overlapping the active layer; a buffer layer on the substrate and covering the light blocking conductive layer; an interlayer insulating layer on the buffer layer and covering the thin film transistor; and a via layer on the interlayer insulating layer. The interlayer insulating layer is in contact with the buffer layer through each of the first through hole and the second through hole.

The first power line is in the light blocking conductive layer. A first electrode of the first thin film transistor is electrically connected to the first power line through a power connection hole penetrating through the gate insulating layer and the buffer layer. A second electrode of the first thin film transistor is electrically connected to the light blocking electrode through a light blocking connection hole penetrating through the gate insulating layer and the buffer layer.

A thin film transistor according to one or more embodiments includes an active layer on a substrate, a gate insulating layer on a portion of the active layer, and a gate electrode, a first electrode, and a second electrode in an electrode conductive layer on the gate insulating layer.

As such, the gate electrode, the first electrode, and the second electrode are formed as the same layer, and accordingly, the number of mask processes required for manufacturing the thin film transistor may be decreased.

In addition, the active layer includes a channel area overlapping the gate electrode, a first conductive area connected to one side of the channel area, and a second conductive area connected to the other side of the channel area.

The thin film transistor according to one or more embodiments further includes a first through hole penetrating through a portion of the first conductive area and a second through hole penetrating through a portion of the second conductive area due to a manufacturing process having a decreased number of mask processes.

The first electrode may be adjacent to one side of the first through hole and be electrically connected to the first conductive area of the active layer. That is, one side of the first electrode adjacent to one side of the first through hole is parallel to one side of the first through hole.

A portion of the first conductive area is removed by the first through hole, and accordingly, the first electrode is in contact with a first pass area between one side of the first through hole and one side of the first electrode in the first conductive area. Therefore, resistance between the first electrode and the first conductive area may be affected by a length of the first pass area.

Accordingly, in one or more embodiments, one side of the first electrode adjacent to one side of the first through hole includes protrusion parts at both ends thereof and a groove part concavely recessed from the gate electrode as compared with the protrusion parts.

As such, one side of the first electrode includes the groove part, and accordingly, a length of the first pass area between the first electrode and the first through hole in the first conductive area is not limited to a length within a width of one side of the first through hole and may become greater than the width of one side of the first through hole.

In other words, the length of the first pass area may be increased as compared with the width of one side of the first through hole by a width of the groove part more concavely recessed than the protrusion parts without increasing the width of one side of the first through hole.

In addition, the second electrode may be symmetrical to the first electrode with respect to the gate electrode. Accordingly, a length of a second pass area between one side of the second through hole and the second electrode in the second conductive area may become greater than a width of one side of the second through hole.

Consequently, resistance between the first conductive area and the first electrode may be decreased by an increased length of the first pass area. In addition, resistance between the second conductive area and the second electrode may be decreased by an increased length of the second pass area.

Accordingly, current characteristics of the thin film transistor may be improved, and thus, uniformity of the current characteristics of the thin film transistor may be improved.

In a transistor array substrate according to an embodiment, pixel drivers of sub-pixels include the thin film transistors in which resistance between each of the first electrode and the second electrode and the active layer is decreased, and accordingly, a difference in driving current due to a difference in current characteristics between the thin film transistors may be reduced. Consequently, a luminance difference due to a difference in driving current for each sub-pixel may be reduced, and thus, display quality of a display device having a transistor array substrate may be improved.

However, the effects, aspects, and features of the present disclosure are not limited to the aforementioned effects, aspects, and features, and various other effects, aspects, and features are included in the present disclosure.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to one or more embodiments;

FIG. 2 is a plan view illustrating the display device of FIG. 1;

FIG. 3 is a cross-sectional view taken along the line A-A′ of FIG. 1;

FIG. 4 is a layout diagram illustrating an example of a circuit layer of a transistor array substrate of FIG. 3;

FIG. 5 is an equivalent circuit diagram illustrating an example of one pixel driver corresponding to one sub-pixel of the transistor array substrate of FIG. 4;

FIG. 6 is a plan view illustrating a first example of a first thin film transistor of s the pixel driver of FIG. 5;

FIG. 7 is a cross-sectional view taken along the line B-B′ of FIG. 6;

FIG. 8 is an enlarged view illustrating a portion C of FIG. 6;

FIG. 9 is a plan view illustrating a comparative example different from that of FIG. 6;

FIG. 10 is an enlarged view illustrating a portion D of FIG. 9;

FIG. 11 is a plan view illustrating a second example of a first thin film transistor of the pixel driver of FIG. 5;

FIG. 12 is a plan view illustrating a third example of a first thin film transistor of the pixel driver of FIG. 5;

FIG. 13 is a flowchart illustrating a method of manufacturing a transistor array substrate according to one or more embodiments; and

FIGS. 14 to 26 are views illustrating processes related to respective steps of FIG. 13.

### DETAILED DESCRIPTION

Embodiments of the present disclosure will now be described more fully hereinafter with reference to the accompanying drawings. The embodiments may, however, be provided in different forms and should not be construed as limiting. The same reference numbers indicate the same components throughout the present disclosure. In the accompanying figures, the thickness of layers and regions may be exaggerated for clarity.

Some of the parts that are not associated with the description may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and/or vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the spirit and scope of the present disclosure herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

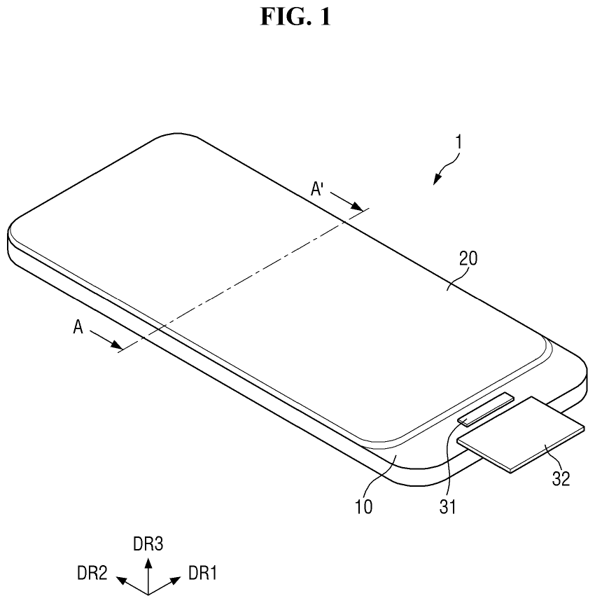

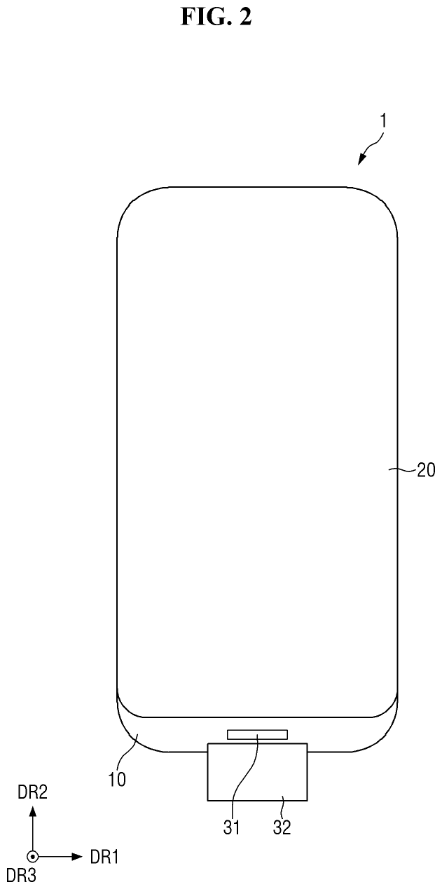

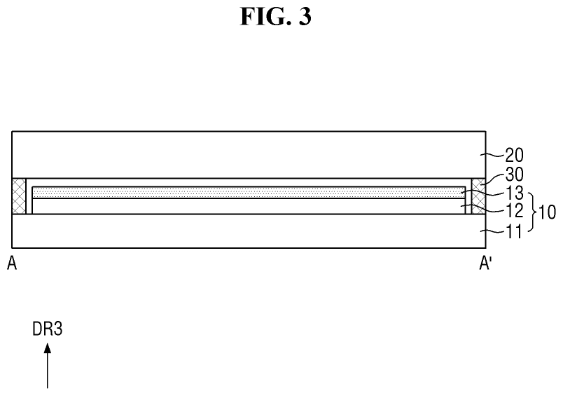

FIG. 1 is a perspective view illustrating a display device according to one or more embodiments. FIG. 2 is a plan view illustrating the display device of FIG. 1. FIG. 3 is a cross-sectional view taken along the line A-A′ of FIG. 1.

Referring to FIGS. 1 and 2, a display device 1 is a device that displays a moving image or a still image, and may be used as a display screen of various products such as televisions, laptop computers, monitors, billboards, and the Internet of Things (IOT) as well as portable electronic devices such as mobile phones, smartphones, tablet personal computers (PCs), smart watches, watch phones, mobile communication terminals, electronic notebooks, electronic books, portable multimedia players (PMPs), navigation devices, and/or ultra mobile PCs (UMPCs).

The display device 1 may be a light emitting display device such as an organic light emitting display device using an organic light emitting diode (OLED), a quantum dot light emitting display device including a quantum dot light emitting layer, an inorganic light emitting display device including an inorganic semiconductor, and a micro light emitting display device using a micro or nano light emitting diode (micro LED or nano LED). Hereinafter, it will be mainly described that the display device 1 is an organic light emitting diode (OLED) display. However, the present disclosure is not limited thereto, and may be applied to a display device including an organic insulating material, an organic light emitting material, and a metal material.

The display device 1 may be formed to be flat, but is not limited thereto. For example, the display device 1 may include curved surface parts formed at left and right ends thereof and having a constant curvature or a variable curvature. In addition, the display device 1 may be flexibly formed to be curved, bent, folded, and/or rolled.

The display device 1 may include a transistor array substrate 10.

The display device 1 may further include a cover substrate 20 facing the transistor array substrate 10 and covering a light emitting element layer 13 (e.g., see FIG. 3).

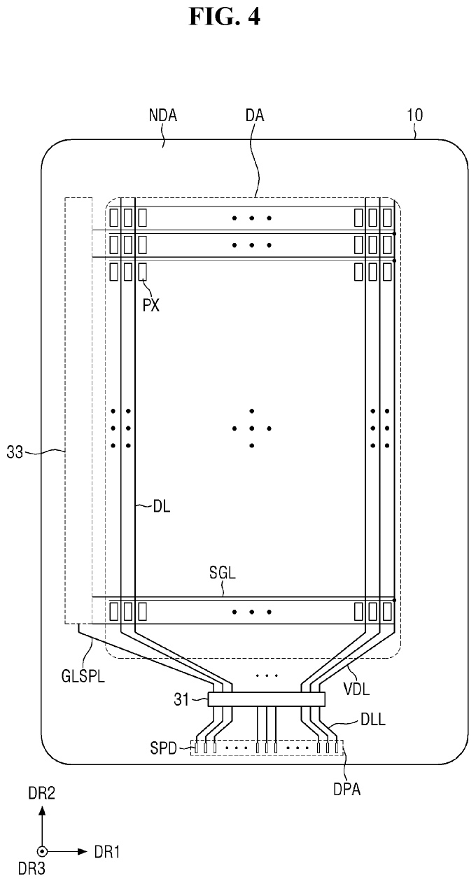

In addition, the display device 1 may further include a display driving circuit 31 for supplying respective data signals to data lines DL (e.g., see FIG. 4) of a circuit layer 12 (e.g., see FIG. 3) of the transistor array substrate 10 and a circuit board 32 for supplying various signals and power to the transistor array substrate 10 and the display driving circuit 31.

Referring to FIG. 3, a transistor array substrate 10 may include a substrate 11 and a circuit layer 12 disposed on the substrate 11.

The transistor array substrate 10 may further include a light emitting element layer 13 disposed on the circuit layer 12.

That is, the light emitting element layer 13 is disposed between the substrate 11 and the cover substrate 20.

The circuit layer 12 supplies a driving signal of each of sub-pixels corresponding to an image signal to the light emitting element layer 13. The light emitting element layer 13 may emit light of each of the sub-pixels according to the driving signal. The light of the light emitting element layer 13 may be emitted to the outside through at least one of the substrate 11 and the cover substrate 20. Consequently, the display device 1 may provide a function of displaying an image.

In addition, the display device 1 may further include a touch sensing unit sensing coordinates of a point touched by a user on a display surface on which the light for displaying an image is emitted.

The touch sensing unit may be attached to one surface of the cover substrate 20 or embedded between the transistor array substrate 10 and the cover substrate 20.

The touch sensing unit may include touch electrodes arranged in a touch sensing area corresponding to the display surface and made of a transparent conductive material.

Such a touch sensing unit may detect whether or not a touch input exists and coordinates of a point where a touch is input by periodically sensing changes in capacitance values of the touch electrodes in a state in which touch driving signals are applied to the touch electrodes.

The cover substrate 20 may face and may be bonded to the transistor array substrate 10.

The cover substrate 20 may be a means providing rigidity for defending against external physical and electrical shocks. The cover substrate 20 may be made of a transparent material having an insulation property and rigidity.

In addition, the display device 1 may further include a sealing layer 30 disposed at an edge between the transistor array substrate 10 and the cover substrate 20 and bonding the transistor array substrate 10 and the cover substrate 20 to each other.

In addition, the display device 1 may further include a filling layer filling a space between the transistor array substrate 10 and the cover substrate 20.

As illustrated in FIGS. 1 and 2, the display surface of the display device 1 may have a rectangular shape having short sides in a first direction (X-axis direction) and long sides in a second direction (Y-axis direction) crossing the first direction (X-axis direction). However, this is only an example, and a shape of the display surface of the display device 1 may be implemented in various forms.

As an example, the display surface may have a shape in which a corner where the short side in the first direction (X-axis direction) and the long side in the second direction (Y-axis direction) meet is rounded with a suitable curvature (e.g., a predetermined curvature). Alternatively, the display surface may have a shape such as a polygonal shape, a circular shape, and/or an elliptical shape.

FIG. 1 has illustrated that the transistor array substrate 10 has a flat plate shape, but the present disclosure is not limited thereto. That is, the transistor array substrate 10 may have a shape in which both ends thereof in the Y-axis direction are bent. Alternatively, the transistor array substrate 10 may be flexibly provided to be curved, bent, folded, or rolled.

The display driving circuit 31 outputs signals and voltages for driving the transistor array substrate 10.

For example, the display driving circuit 31 may supply data signals to data lines DL (e.g., see FIG. 4) of the transistor array substrate 10 and supply first driving power to first driving power lines VDL (e.g., see FIG. 4) of the transistor array substrate 10. In addition, the display driving circuit 31 may supply scan control signals to a gate driver 33 (e.g., see FIG. 4) embedded in the transistor array substrate 10.

The display driving circuit 31 may be provided as an integrated circuit (IC).

An integrated circuit chip of the display driving circuit 31 may be directly mounted on the transistor array substrate 10 in a chip on glass (COG) manner, a chip on plastic (COP) manner, and/or an ultrasonic bonding manner. In this case, as illustrated in FIG. 2, the integrated circuit chip of the display driving circuit 31 may be disposed in an area of the transistor array substrate 10 that is not covered with the cover substrate 20.

Alternatively, the integrated circuit chip of the display driving circuit 31 may be mounted on the circuit board 32.

The circuit board 32 may include an anisotropic conductive film. The circuit board 32 may be a flexible printed circuit board, a printed circuit board, and/or a flexible film such as a chip on film.

The circuit board 32 may be attached to electrode pads of the transistor array substrate 10. Therefore, lead lines of the circuit board 32 may be electrically connected to the electrode pads of the transistor array substrate 10.

FIG. 4 is a layout diagram illustrating an example of a circuit layer of a transistor array substrate of FIG. 3.

Referring to FIG. 4, the transistor array substrate 10 may include a display area DA in which light for displaying an image is emitted and a non-display area NDA that is a peripheral area of the display area DA, the non-display area NDA is around an edge or periphery of the display area DA. The non-display area NDA may be an area from an edge of the display area DA to an edge of the substrate 11 (e.g., see FIG. 3).

The transistor array substrate 10 includes sub-pixels PX arranged in a matrix shape along longitudinal and transverse directions in the display area DA. Each of the sub-pixels PX may be a unit individually displaying luminance and color.

The non-display area NDA may include a display pad area DPA disposed adjacent to the edge of the substrate 11. The transistor array substrate 10 may further include signal pads SPD disposed in the display pad area DPA of the non-display area NDA.

The circuit board 32 may be attached to the display pad area DPA of the transistor array substrate 10 and electrically connected to the signal pads SPD.

The transistor array substrate 10 further includes lines disposed in the display area DA and supplying signals or power to a plurality of sub-pixels PX. The lines of the transistor array substrate 10 may include scan gate lines SGL, data lines DL, and first power lines VDL.

The scan gate lines SGL may extend in the first direction DR1.

The data lines DL may extend in the second direction DR2 crossing the first direction DR1.

The first power lines VDL may extend in one of the first direction DR1 and the second direction DR2. As an example, the first power lines VDL may extend in the second direction DR2 like the data lines DL.

Alternatively, the circuit layer 12 (e.g., see FIG. 3) may further include first power auxiliary lines extending in a direction crossing the first power lines VDL and electrically connected to the first power lines VDL in order to decrease an RC delay of the supply of first power due to resistance of the first power lines VDL.

The scan gate lines SGL transfers scan signals for controlling whether or not to transfer data signals, to the sub-pixels PX.

The scan gate lines SGL may be connected to a gate driver 33 disposed in a portion of the non-display area NDA of the transistor array substrate 10.

The gate driver 33 may be electrically connected to the display driving circuit 31 or at least one of the signal pads SPD through at least one gate control supply line GLSPL.

The gate driver 33 may apply scan signals to the scan gate lines SGL based on gate control signals, gate level power, and the like, supplied through at least one gate control supply line GLSPL.

As illustrated in FIG. 4, the gate driver 33 is disposed in a portion of the non-display area NDA adjacent to one side (i.e., the left side of FIG. 4) of the display area DA in the first direction DR1. However, this is only an example, and the gate driver 33 may be also disposed in another portion of the non-display area NDA adjacent to the right side of the display area DA. Alternatively, the gate drivers 33 may be disposed on both sides of the display area DA in the left and right direction.

The data lines DL are electrically connected between the display driving circuit 31 and the sub-pixels PX, and transfer the data signals output from the display driving circuit 31 to the sub-pixels PX.

The display driving circuit 31 may be electrically connected to some of the signal pads SPD through data connection lines DLL. That is, the display driving circuit 31 may be electrically connected to the circuit board 32 through the data connection line DLLs and some signal pads SPD.

The circuit board 32 may supply digital video data corresponding to an image signal and timing signals to the display driving circuit 31.

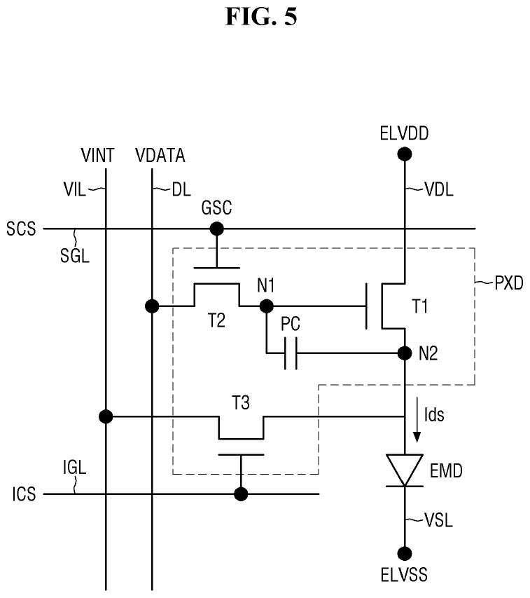

The circuit layer 12 (e.g., see FIG. 3) may further include first power lines VDL and second power lines that extend from the non-display area NDA to the display area DA and each transfer a first power ELVDD (e.g., see FIG. 5) and a second power ELVSS (e.g., see FIG. 5) for driving light emitting elements EMD (e.g., see FIG. 5). Here, the second power ELVSS may have a lower voltage level than the first power ELVDD.

Each of the first power lines VDL and the second power lines may be electrically connected to the display driving circuit 31 or at least one of the signal pads SPD.

The circuit layer 12 includes pixel drivers PXD (e.g., see FIG. 5) each corresponding to the sub-pixels PX and electrically connected to the scan gate lines SGL, the data lines DL, and the first power lines VDL.

FIG. 5 is an equivalent circuit diagram illustrating an example of one pixel driver corresponding to one sub-pixel of the transistor array substrate of FIG. 4.

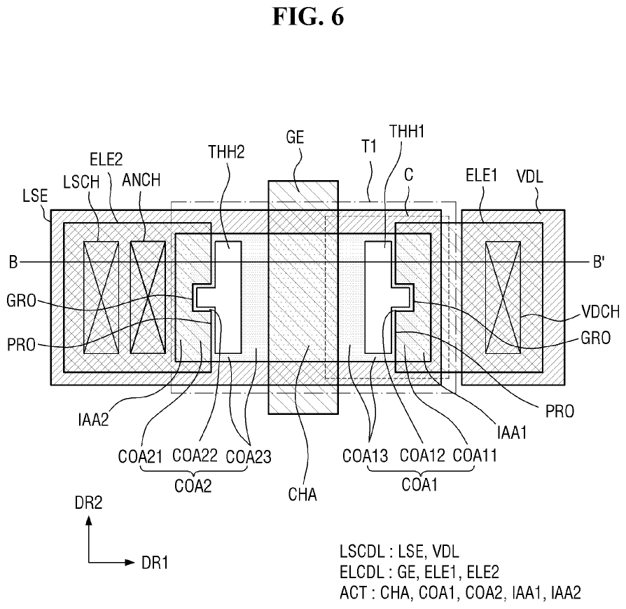

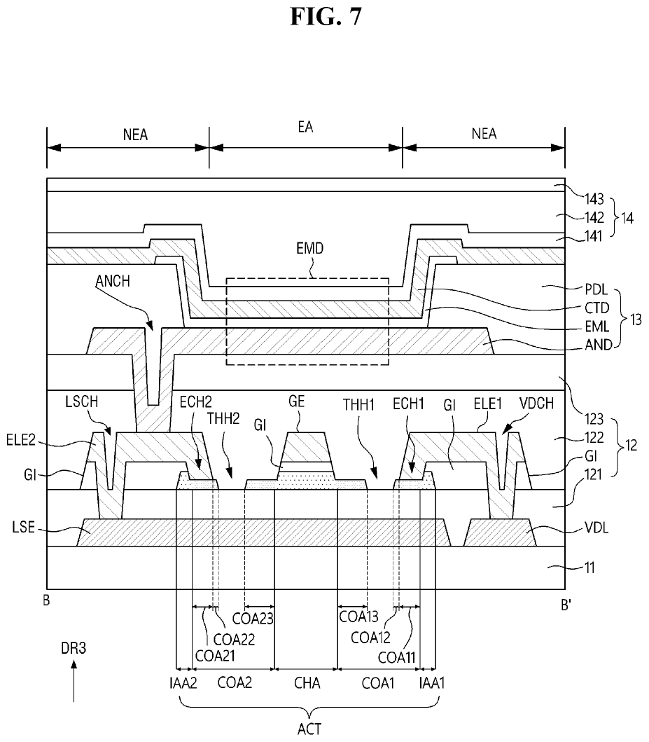

Referring to FIG. 5, one of the pixel drivers PXD of the transistor array substrate 12 is electrically connected to one of the light emitting elements EMD of the light emitting element layer 13. That is, one pixel driver PXD may be electrically connected to an anode electrode AND (e.g., see FIGS. 6 and 7) of one light emitting element EMD and may supply a driving current corresponding to a data signal VDATA of the data line DL.

One light emitting element EMD may be an organic light emitting diode (OLED) including a light emitting layer made of an organic material. Alternatively, one light emitting element EMD may include a light emitting layer made of an inorganic material. Alternatively, the light emitting element EMD may be a quantum dot light emitting element including a quantum dot light emitting layer. Alternatively, the light emitting element EMD may be a micro light emitting diode.

One pixel driver PXD may include one or more thin film transistors T1, T2, and T3.

As an example, one pixel driver PXD may include a first thin film transistor T1, a second thin film transistor T2, and a third thin film transistor T3. In addition, one pixel driver PXD may further include a pixel capacitor PC.

The first thin film transistor T1 is connected to the light emitting element EMD in series between the first power line VDL and the second power line VSL. That is, a first electrode (e.g., a source electrode) of the first thin film transistor T1 may be electrically connected to the first power line VDL, and a second electrode (e.g., a drain electrode) of the first thin film transistor T1 may be electrically connected to the anode electrode AND of the light emitting element EMD.

A cathode electrode CTD (e.g., see FIG. 7) of the light emitting element EMD may be electrically connected to the second power line VSL.

In addition, a gate electrode of the first thin film transistor T1 may be electrically connected to the second thin film transistor T2 via a first node N1.

The second thin film transistor T2 may be electrically connected between the data line DL and the gate electrode of the first thin film transistor T1 and may be turned on based on a scan signal SCS of the scan gate line SGL.

That is, when the scan signal SCS is applied to the second thin film transistor T2 through the scan gate line SGL, the second thin film transistor T2 may be turned on and the data line DL and the gate electrode of the first thin film transistor T1 may be electrically connected to each other. In this case, the data signal VDATA of the data line DL may be supplied to the pixel capacitor PC and the gate electrode of the first thin film transistor T1 through the turned-on second thin film transistor T2 and the first node is N1.

The first thin film transistor T1 may be turned on when a voltage difference between the gate electrode and the first electrode becomes greater than a threshold voltage. That is, when the data signal VDATA is applied to the first thin film transistor T1 through the first node N1, the voltage difference between the gate electrode and the first electrode of the first thin film transistor T1 becomes greater than the threshold voltage by the first power ELVDD and the data signal VDATA, such that the first thin film transistor T1 may be turned on. In this case, a current Ids between the first electrode and the second electrode of the first thin film transistor T1 is supplied as a driving current of the light emitting element EMD. In addition, a magnitude of the current Ids between the first electrode and the second electrode of the first thin film transistor T1 corresponds to the data signal VDATA. That is, the driving current Ids corresponding to the data signal VDATA is supplied to the light emitting element EMD, and thus, the light emitting element EMD may emit light having luminance corresponding to the data signal VDATA.

The pixel capacitor PC may be electrically connected between the first node N1 and a second node N2. The first node N1 is a contact point between the gate electrode of the first thin film transistor T1 and the second thin film transistor T2. The second node N2 is a contact point between the first thin film transistor T1 and the light emitting element EMD.

Due to such an arrangement of the pixel capacitor PC, a potential difference between the gate electrode and the second electrode of the first thin film transistor T1 may be maintained until a potential of the first node N1 is changed according to the data signal VDATA.

The third thin film transistor T3 may be electrically connected between an initialization voltage line VIL and the second node N2. A gate electrode of the third thin film transistor T3 may be electrically connected to an initialization gate line IGL.

That is, when an initialization control signal ICS is applied to the third thin film transistor T3 through the initialization gate line IGL, the third thin film transistor T3 may be turned on and the initialization voltage line VIL and the second node N2 may be electrically connected to each other. In this case, an initialization voltage VINT of the initialization voltage line VIL may be supplied to the anode AND of the light emitting element EMD through the turned-on third thin film transistor T3 and the second node N2. Consequently, a potential of the anode electrode AND may be initialized to the initialization voltage VINT.

FIG. 5 illustrates that the pixel driver PXD has a 3T1C structure including the first thin film transistor T1, the second thin film transistor T2, the third thin film transistor T3, and one pixel capacitor PC, but this is only an example. That is, a structure of the pixel driver PXD according to one or more embodiments is not limited to the 3T1C structure illustrated in FIG. 5, and may also be changed into a structure different from the structure illustrated in FIG. 5 if necessary. As an example, the pixel driver PXD may further include a thin film transistor for initializing the potential of the first node N1.

In addition, FIG. 5 illustrates a case where one or more thin film transistors T1, T2, and T3 included in the pixel driver PXD are formed as N-type metal oxide semiconductor field effect transistors (MOSFETs), but this is only an example. That is, at least one of the one or more thin film transistors T1, T2, and T3 included in the pixel driver PXD may also be a P-type MOSFET.

FIG. 6 is a plan view illustrating a first example of a first thin film transistor of the pixel driver of FIG. 5. FIG. 7 is a cross-sectional view taken along the line B-B′ of FIG. 6.

Referring to FIGS. 6 and 7, the first thin film transistor T1 included in one of the pixel drivers PXD of the circuit layer 12 of the transistor array substrate 10 according to one or more embodiments includes an active layer ACT disposed on the substrate 11 and a gate electrode GE, a first electrode ELE1, and a second electrode ELE2 formed as an electrode conductive layer ELCDL on a gate insulating layer GI covering the active layer ACT.

When one pixel driver PXD further includes the second thin film transistor T2 and the third thin film transistor T3 as illustrated in FIG. 5, the second thin film transistor T2 and the third thin film transistor T3 are substantially the same as or similar to the first thin film transistor T1 illustrated in FIGS. 6 and 7, and thus, an overlapping description thereof will hereinafter be omitted.

For reference, in the following description, the first thin film transistor T1 of FIGS. 6 and 7 may be simply referred to as a thin film transistor T1.

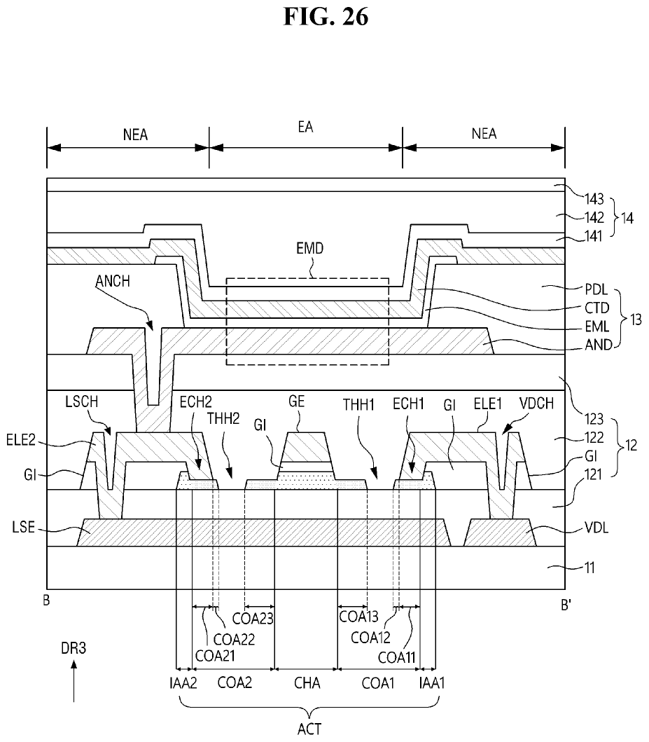

In addition, in the following description of FIGS. 6 to 26, the first direction DR1 may be referred to as a direction in which each of the first and second electrodes ELE1 and ELE2 and the gate electrode GE face each other or an extension direction of the active layer ACT, and the second direction DR2 may be referred to as a direction crossing the first direction DR1 or an extension direction of the gate electrode GE. That is, the first direction DR1 and the second direction DR2 in FIGS. 6 to 26 may be the same as the first direction DR1 and the second direction DR2 in FIGS. 1 to 4, respectively, but may also be different from the first direction DR1 and the second direction DR2 in FIGS. 1 to 4, respectively, depending on a structure of the active layer ACT.

As illustrated in FIG. 6, the active layer ACT includes a channel area CHA, a first conductive area COA1 connected to one side of the channel area CHA, and a second conductive area COA2 connected to the other side of the channel area CHA.

The channel area CHA of the active layer ACT overlaps the gate electrode GE in a third direction DR3 (e.g., a thickness direction of the substrate 11). Because the channel area CHA is in a state in which it is covered with the gate insulating layer GI disposed beneath the gate electrode GE, semiconductor characteristics of the channel area CHA may be maintained. Consequently, a channel, which is a movement passage of carriers, may be selectively generated in the channel area CHA according to a potential of the gate electrode GE.

The first conductive area COA1 of the active layer ACT may correspond to a first electrode connection hole ECH1 (e.g., see FIG. 7) penetrating through the gate insulating layer GI. That is, the first conductive area COA1 is exposed to an etching material or the like through the first electrode connection hole ECH1, such that a content of oxygen is decreased or a content of hydrogen is increased in the first conductive area COA1 as compared with the channel area CHA, and thus, the first conductive area COA1 may be in a state in which it becomes conductive.

Similarly, the second conductive area COA2 of the active layer ACT may correspond to a second electrode connection hole ECH2 (e.g., see FIG. 7) penetrating through the gate insulating layer GI. That is, the second conductive area COA2 is exposed to an etching material or the like through the second electrode connection hole ECH2, such that a content of oxygen is decreased or a content of hydrogen is increased in the second conductive area COA2 as compared with the channel area CHA, and thus, the second conductive area COA2 may be in a state in which it becomes conductive.

According to one or more embodiments, the electrode conductive layer ELCDL on the gate insulating layer GI covering a portion of the active layer ACT includes the gate electrode GE, the first electrode ELE1, and the second electrode ELE2. In this manner, the number of mask processes required for disposing the thin film transistor T1 may be decreased.

As described above, according to one or more embodiments, due to a manufacturing process with a decreased number of mask processes, the first thin film transistor T1 further includes a first through hole THH1 penetrating through a portion of the first conductive area COA1 and a second through hole THH2 penetrating through a portion of the second conductive area COA2.

The first electrode ELE1 is adjacent to one side of the first through hole THH1, and one side of the first electrode ELE1 adjacent to the first through hole THH1 is parallel to one side of the first through hole THH1.

In addition, the first electrode ELE1 may extend toward the first conductive area COA1 to be in contact with a first contact area COA11 of the first conductive area COA1. Consequently, the first electrode ELE1 is electrically connected to the first conductive area COA1.

In addition, as described above, a portion of the first conductive area COA1 is removed by the first through hole THH1.

Accordingly, the first conductive area COA1 may include the first contact area COA11 in contact with the first electrode ELE1, a first pass area COA12 disposed between one side of the first through hole THH1 and the first contact area COA11, and a first main area COA13 disposed between the channel area CHA and the first pass area COA12.

Because the first contact area COA11 is in contact with the first electrode ELE1, the first pass area COA12 is disposed between the first through hole THH1 and the first electrode ELE1.

The first through hole THH1 has a width smaller than that of the first conductive area COA1, and accordingly, the other portions of an edge of the first through hole THH1 except for one side of the edge of the first through hole THH1 adjacent to the first electrode ELE1 may be in contact with the first main area COA13.

That is, in the first direction DR1 in which the gate electrode GE and the first electrode ELE1 face (e.g., oppose) each other, one side (right side of FIG. 6) of the first through hole THH1 is adjacent to the first electrode ELE1 and is in contact with the first pass area COA12. In addition, the other side (left side of FIG. 6) of the first through hole THH1 in the first direction DR1 may be in contact with the first main area COA13.

In the second direction DR2 crossing the first direction DR1, both sides (upper and lower sides in FIG. 6) of the first through hole THH1 may be in contact with the first main area COA13.

One side of the first electrode ELE1 of the first thin film transistor T1 according to one or more embodiments disposed in parallel with the first through hole THH1 includes protrusion parts PRO disposed at both ends thereof in the second direction DR2 and a groove part GRO concavely recessed from the gate electrode GE as compared with the protrusion parts PRO.

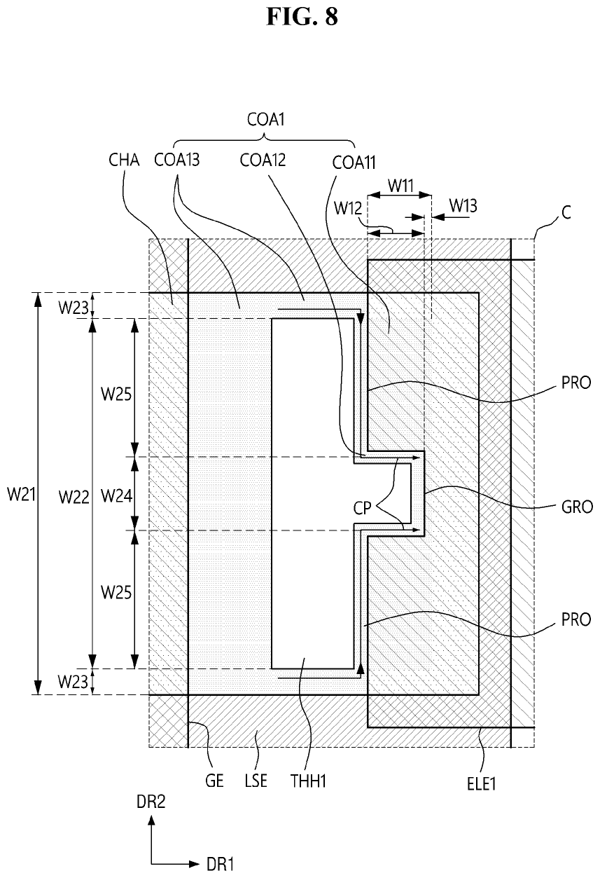

In this manner, one side of the first through hole THH1 and one side of the first electrode ELE1 facing each other are parallel to each other, and thus, a length of the first contact area COA12 between the first electrode ELE1 and the first through hole THH1 may not be limited to a length within the width of the first through hole THH1 due to the groove part GRO of the first electrode ELE1. As a result, resistance between the first electrode ELE1 and the first conductive area COA1 may be lowered, and thus, current characteristics of the first thin film transistor T1 may be improved. This will be described in detail below with reference to FIG. 8.

The second electrode ELE2 is adjacent to one side of the second through hole THH2, and one side of the second electrode ELE2 adjacent to the second through hole THH2 is parallel to one side of the second through hole THH2.

The second electrode ELE2 may extend to the second conductive area COA2 to be in contact with a second contact area COA21 of the second conductive area COA2. Consequently, the second electrode ELE2 is electrically connected to the second conductive area COA2.

A portion of the second conductive area COA2 is removed by the second through hole THH2, and accordingly, the second conductive area COA2 may include the second contact area COA21 in contact with the second electrode ELE2, a second pass area COA22 disposed between one side of the second through hole THH2 and the second contact area COA21, and a second main area COA23 disposed between the channel area CHA and the second pass area COA22.

In addition, the second electrode ELE2 may be symmetrical to the first electrode ELE1 with respect to the gate electrode GE.

That is, similar to the first electrode ELE1, one side of the second electrode ELE2 adjacent to the second through hole THH2 may include protrusion parts PRO and a groove part GRO.

As illustrated in FIGS. 6 and 7, the first conductive area COA1 and the second conductive area COA2 of the active layer ACT correspond the first electrode connection hole ECH1 and the second electrode connection hole ECH2, respectively. Accordingly, due to arrangement margins of the first electrode connection hole ECH1 and the second electrode connection hole ECH2, the active layer ACT may further include a first inactive area IAA1 and a second inactive area IAA2.

The first inactive area IAA1 is connected to the first contact area COA11 of the first conductive area COA1 and is covered with the gate insulating layer GI. The first inactive area IAA1 may overlap the first electrode ELE1 in the third direction DR3.

The second inactive area IAA2 is connected to the second contact area COA21 of the second conductive area COA2 and is covered with the gate insulating layer GI. The second inactive area IAA2 may overlap the second electrode ELE2.

The circuit layer 12 of the transistor array substrate 10 according to one or more embodiments may further include a light blocking electrode LSE comprised in a light blocking conductive layer LSCDL on the substrate 11 and overlapping the active layer ACT and a buffer layer 121 disposed on the substrate 11 and covering the light blocking conductive layer LSCDL. For example, the buffer layer 121 may be disposed between the light blocking conductive layer LSCDL and active layer ACT.

In addition, the circuit layer 12 may further include an interlayer insulating layer 122 disposed on the buffer layer 121 and covering the gate electrode GE, the first electrode ELE1, and the second electrode ELE2 of the thin film transistor T1 and a via layer 123 disposed on the interlayer insulating layer 122.

The first through hole THH1 and the second through hole THH2 of the first thin film transistor T1 penetrate through portions of the first conductive area COA1 and the second conductive area COA2 of the active layer ACT that are not covered with the gate insulating layer GI, and accordingly, the interlayer insulating layer 122 may be in contact with the buffer layer 121 through the first through hole THH1 and the second through hole THH2.

The substrate 11 may be made of an insulating material such as a polymer resin. For example, the substrate 11 may be made of polyimide. The substrate 11 may be a flexible substrate that may be bent, folded, and rolled.

Alternatively, the substrate 11 may be made of a rigid insulating material such as glass.

Each of the buffer layer 121, the gate insulating layer GI, and the interlayer insulating layer 122 may be formed as at least one inorganic film. As an example, each of the buffer layer 121, the gate insulating layer GI, and the interlayer insulating layer 122 may be formed as multiple films in which one or more inorganic films of a silicon nitride film, a silicon oxynitride film, a silicon oxide film, a titanium oxide film, and/or an aluminum oxide film are alternately stacked.

Alternatively, the interlayer insulating layer 122 may be formed as an organic film made of an acrylic resin, an epoxy resin, a phenolic resin, a polyamide resin, a polyimide resin, and/or the like.

The via layer 123 may be flatly disposed on the interlayer insulating layer 122. Such a via layer 123 may be formed as an organic film made of an acrylic resin, an epoxy resin, a phenolic resin, a polyamide resin, a polyimide resin, and/or the like.

The light blocking conductive layer LSCDL on the substrate 11 may be formed as a single layer or multiple layers made of one or more selected from among molybdenum (Mo), aluminum (Al), chromium (Cr), gold (Au), titanium (Ti), nickel (Ni), neodymium (Nd), and/or copper (Cu), and/or alloys thereof.

As an example, the light blocking conductive layer LSCDL may have a double layer structure including a diffusion barrier layer and a low resistance layer. The diffusion barrier layer of the light blocking conductive layer LSCDL may be made of titanium (Ti). In addition, the low resistance layer of the light blocking conductive layer LSCDL may be made of copper (Cu).

The light blocking conductive layer LSCDL may further include a first power line VDL.

In addition, in one or more embodiments, the light blocking conductive layer LSCDL may further include at least one of a data line DL and an initialization voltage line VIL.

The light blocking electrode LSE overlaps the active layer ACT and blocks light from the substrate 11 toward the active layer ACT.

Alternatively, the light blocking electrode LSE may overlap only a portion of the active layer ACT including at least the channel area CHA in the third direction DR3.

Due to such a light blocking electrode LSE, a leakage current of the active layer ACT may be prevented.

The active layer ACT may be disposed on the buffer layer 121 covering (e.g., overlapping) the light blocking conductive layer LSCDL.

The active layer ACT may be made of one or more semiconductor materials selected from among polysilicon, amorphous silicon, and/or an oxide semiconductor.

The gate insulating layer GI is disposed on the buffer layer 121 and covers a portion of the active layer ACT.

The electrode conductive layer ELCDL on the gate insulating layer GI may be formed as a single layer or multiple layers including one or more selected from among molybdenum (Mo), aluminum (Al), chromium (Cr), gold (Au), titanium (Ti), nickel (Ni), neodymium (Nd), and/or copper (Cu), and/or alloys thereof.

As an example, the electrode conductive layer ELCDL may be formed as multiple layers including a diffusion barrier layer, a low resistance layer, and a cover layer. The diffusion barrier layer of the electrode conductive layer ELCDL may include titanium (Ti). The low resistance layer of the electrode conductive layer ELCDL may include at least one selected from among aluminum (Al), chromium (Cr), gold (Au), nickel (Ni), neodymium (Nd), and/or copper (Cu). The cover layer of the electrode conductive layer ELCDL may be made of indium tin oxide (ITO) in order to prevent corrosion and easily bond the signal pads SPD thereto.

The electrode conductive layer ELCDL is disposed on the gate insulating layer GI and includes the gate electrode GE, the first electrode ELE1 and the second electrode ELE2.

In addition, the electrode conductive layer ELCDL may further include at least one of a scan gate line SGL, the first power line VDL, and/or an initialization gate line IGL.

The first electrode ELE1 of the first thin film transistor T1 may be electrically connected to the first power line VDL through a power connection hole VDCH penetrating through the gate insulating layer GI and the buffer layer 121.

An anode electrode AND of the light emitting element layer 13 disposed on the via layer 123 may be electrically connected to the second electrode ELE2 of the first thin film transistor T1 through an anode contact hole ANCH penetrating through the interlayer insulating layer 122 and the via layer 123.

In addition, the second electrode ELE2 of the first thin film transistor T1 may be electrically connected to the light blocking electrode LSE through a light blocking connection hole LSCH penetrating through the gate insulating layer GI and the buffer layer 121. Consequently, a potential of the second node N2 between the first thin film transistor T1 and the light emitting element EMD may be stably maintained.

The transistor array substrate 10 according to one or more embodiments may include the light emitting element layer 13 disposed on the via layer 123 of the circuit layer 12.

The light emitting element layer 13 includes the light emitting elements EMD each corresponding to the sub-pixels PX. One of the light emitting elements EMD may include an anode electrode AND and a cathode electrode CTD facing (e.g., opposing) each other and a light emitting layer EML interposed between the anode electrode AND and the cathode electrode CTD and made of a photoelectric conversion material.

The light emitting element layer 13 may further include a pixel definition layer PDL covering an edge of the anode electrode AND.

The transistor array substrate 10 according to one or more embodiments may further include a sealing layer 14 disposed on the light emitting element layer 13.

The sealing layer 14 may have a structure in which at least one inorganic film and at least one organic film are alternately stacked. As an example, the sealing layer 14 may include a first inorganic layer 141 disposed on the light emitting element layer 13 and made of an inorganic insulating material, an organic layer 142 disposed on the first inorganic layer 141 and made of an organic insulating material, and a second inorganic layer 143 disposed above the organic layer 142, covering the organic layer 142, and made of an inorganic insulating material.

FIG. 8 is an enlarged view illustrating a portion C of FIG. 6.

Referring to FIG. 8, the thin film transistor T1 according to one or more embodiments includes the first through hole THH1 penetrating through a portion of the first conductive area COA1 connected to one side of the channel area CHA and the first electrode ELE1 formed as the electrode conductive layer ELCDL on the gate insulating layer GI and extending toward the first conductive area COA1 so as to be adjacent to one side of the first through hole THH1.

The first conductive area COA1 may include the first contact area COA11 in contact with the first electrode ELE1, the first pass area COA12 between the first contact area COA11 and the first through hole THH1, and the first main area COA13 between the first pass area COA12 and the channel area CHA.

In the second direction DR2 crossing the first direction DR1 in which the first electrode ELE1 and the gate electrode GE face each other, a width of the active layer ACT, that is, a width W21 of the first conductive area COA1 is greater than a width of the first through hole THH1. That is, the first through hole THH1 may penetrate through a central portion of the first conductive area COA1 and may be surrounded by the first conductive area COA1.

One side of an edge of the first through hole THH1 in the first direction DR1 may be in contact with the first pass area COA12, and the other side of the edge of the first through hole THH1 in the first direction DR1 and both sides of the edge of the first through hole THH1 in the second direction DR2 may be in contact with the first main area COA13.

In this case, portions of the first main area COA13 in contact with both sides of the first through hole THH1 in the second direction DR2 may have widths W23 in the same or similar range. In this manner, current concentration around the first through hole THH1 may be reduced.

When a channel is generated in the channel area CHA, carriers may move between the first conductive area COA1 and the second conductive area COA2.

In this case, carriers CP moving within the first conductive area COA1 may flow from the first main area COA13 to the first contact area COA11 through the first pass area COA12 to arrive at the first electrode ELE1.

Accordingly, a width, a thickness, a length, and/or the like, of the first pass area COA12 may affect the mobility of the thin film transistor T1.

Because the first pass area COA12 is disposed between the first electrode ELE1 and the first through hole THH1, the width of the first pass area COA12 may be limited to an interval between the first electrode ELE1 and the first through hole THH1.

Because the first conductive area COA1 of the thin film transistor T1 is made of a semiconductor material that becomes conductive, the thickness of the first pass area COA12 may be limited by a process condition or the like in a process of making the semiconductor material conductive.

In addition, the length of the first pass area COA12 may correspond to a s length of a portion of the edge of the first electrode ELE1 adjacent to the first through hole THH1.

That is, the length of the first pass area COA12 in the second direction DR2 may correspond to a width W22 of the first through hole THH1 in the second direction DR2.

In addition, a shape of one side (left side of FIG. 8) of the first electrode ELE1 adjacent to the first through hole THH1 may affect the length of the first pass area COA12.

As such, according to one or more embodiments, in order to increase the length of the first pass area COA12, one side (left side of FIG. 8) of the first electrode ELE1 adjacent to the first through hole THH1 in the first direction DR1 includes protrusion parts PRO disposed at both ends thereof in the second direction DR2 and a groove part GRO concavely recessed as compared with the protrusion parts PRO.

In this manner, the length of the first pass area COA12 (e.g., in the second direction DR2) may become greater than the width W22 of the first through hole THH1 in the second direction DR2 by a difference that is in direct proportion to a width W12 of the groove part GRO in the first direction DR1. That is, the length of the first pass area COA12 may not be limited to a length within the width W22 of the first through hole THH1 in the second direction DR2.

That is, the length of the first pass area COA12 may be derived as the sum of the width W22 of the first through hole THH1 in the second direction DR2 and two times of the width W12 of the groove part GRO in the first direction DR1.

The groove part GRO of the first electrode ELE1 overlaps the first contact area COA11. To this end, in the first direction DR1, a maximum width W11 of the first contact area COA11 may be greater than the width W12 of the groove part GRO.

That is, in the first direction DR1, a width W13 of a portion of the first contact area COA11 overlapping the groove part GRO may be derived as a difference between the maximum width W11 of the first contact area COA11 and the width W12 of the groove part GRO. As an example, the width W13 of a portion of the first contact area COA11 overlapping the groove part GRO may be 0.5 μm or more in consideration of an etching margin.

On one side of the first electrode ELE1 adjacent to the first through hole THH1 in the first direction DR1, the protrusion parts PRO and the groove part GRO may be arranged along the second direction DR2.

The protrusion parts PRO may be disposed at both ends of one side of the first electrode ELE1 in the second direction DR2, respectively.

The groove part GRO may be disposed between the protrusion parts PRO.

To this end, a width W24 of the groove part GRO in the second direction DR2 may be equal to or less than ½ of the width W22 of the first through hole THH1 in the second direction DR2. As an example, when the width W22 of the first through hole THH1 in the second direction DR2 is about 4 μm, the width W24 of the groove part GRO in the second direction DR2 may be about 2 μm.

In addition, in consideration an etching margin, the width W24 of the groove part GRO in the second direction DR2 may be about 1 μm or more.

In addition, the groove part GRO may be disposed at the center of one side of the first electrode ELE1 in the second direction DR2. Accordingly, in the second direction DR2, the protrusion parts PRO may have widths W25 in the same or similar range.

The second electrode ELE2 is symmetrical to the first electrode ELE1 with respect to the gate electrode GE, and an overlapping description will thus be omitted.

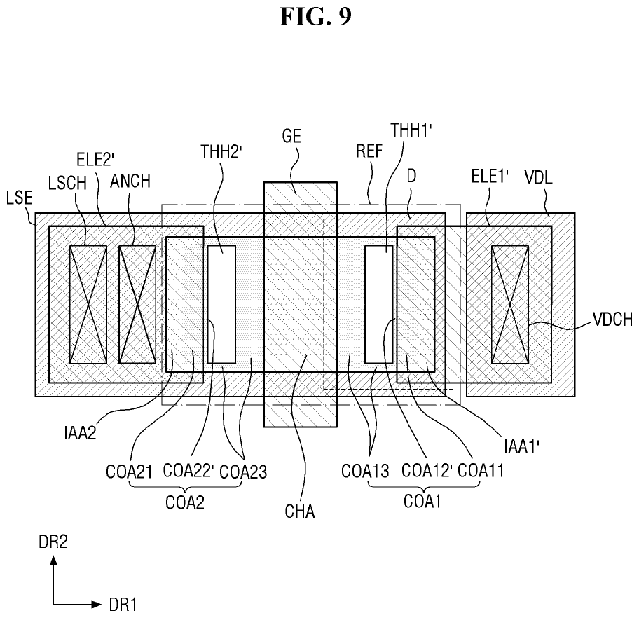

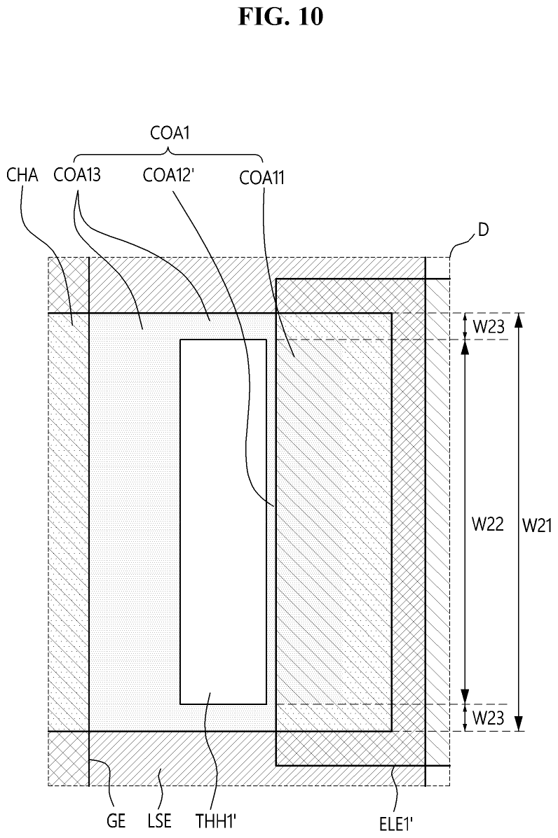

FIG. 9 is a plan view illustrating a comparative example different from that of FIG. 6. FIG. 10 is an enlarged view illustrating a portion D of FIG. 9.

Referring to FIGS. 9 and 10, one side of each of a first electrode ELE1′ and a second electrode ELE2′ of a thin film transistor REF according to a comparative example facing a gate electrode GE is formed in a straight line shape.

As such, according to a comparative example, a length of a first pass area COA12′ is limited to a length within a width W22 of a first through hole THH1′ in the second direction DR2.

In addition, a length of a second pass area COA22′ is limited to a length within a width W22 of a second through hole THH2′ in the second direction DR2.

Accordingly, in the case of a comparative example REF, a decrease in resistance and improvement of mobility by the length of the first pass area COA12′ and the length of the second pass area COA22′ may not be derived.

On the other hand, as illustrated in FIGS. 6 and 8, in the thin film transistor T1 according to one or more embodiments, one side of each of the first electrode ELE1 and the second electrode ELE2 facing the gate electrode GE is formed in an uneven shape including the protrusion parts PRO and the groove part GRO, and accordingly, the length of first pass area COA12 and the length of second pass area COA22 may be increased due to the width of groove part GRO.

Consequently, resistance of the thin film transistor T1 may be decreased, and thus, mobility of the thin film transistor T1 may be increased, such that current characteristics of the thin film transistor T1 may be improved and uniformity of the current characteristics of the thin film transistor T1 may be improved.

In addition, as the uniformity of the current characteristics of the thin film transistor T1 included in the transistor array substrate 10 is improved, a luminance difference between the sub-pixels PX may be improved, and thus, display quality of the display device 1 may be improved.

FIGS. 6 and 7 illustrate the first example in which one side of each of the first electrode ELE1 and the second electrode ELE2 facing the gate electrode GE includes one groove part GRO. However, the thin film transistor T1 according to one or more embodiments is not limited to that illustrated in FIGS. 6 and 7.

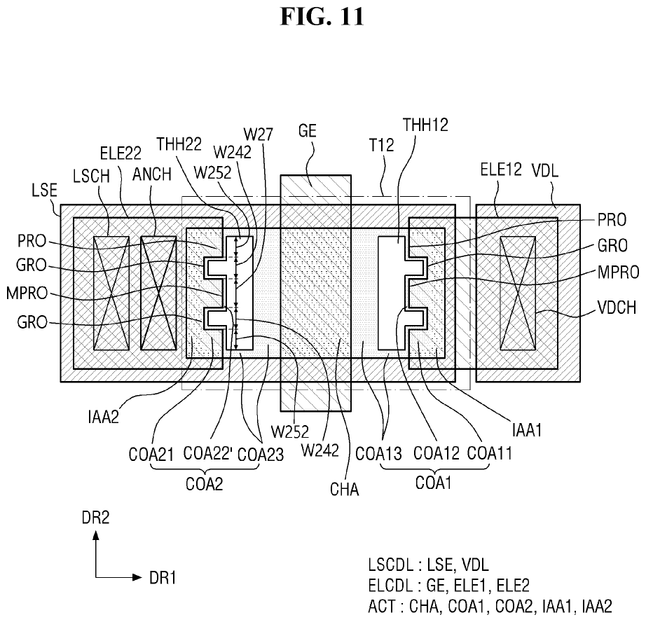

FIG. 11 is a plan view illustrating a second example of a first thin film transistor of the pixel driver of FIG. 5.

Referring to FIG. 11, in a thin film transistor T12 according to one or more embodiments, one side of each of the first electrode ELE12 and the second electrode ELE22 facing the gate electrode GE may include two or more groove parts GRO and a middle protrusion part MPRO disposed between the groove parts GRO. The second example is substantially the same as the first example illustrated in FIGS. 6 to 8 except that the number of groove parts GRO is plural, and an overlapping description will thus be omitted.

Here, the two or more groove parts GRO may have the same width in the first direction DR1.

In this manner, mobility characteristics of the thin film transistor T1 may be easily predicted.

In addition, the two or more groove parts GRO may have the same width W242 in the second direction DR2. The protrusion parts PRO of both ends may have the same width W252 in the second direction DR2.

In this manner, the middle protrusion part MPRO may be disposed at the center of each of the first and second electrodes ELE12 and ELE22 in the second direction DR2, and thus, process errors may be reduced.

A width W27 of the middle protrusion part MPRO in the second direction DR2 may be different from the width W252 of the protrusion parts PRO of both ends in the second direction DR2.

In consideration an etching margin, the width W27 of the middle protrusion part MPRO in the second direction DR2 may be about 1 μm or more.

When one side of each of the first electrode ELE12 and the second electrode ELE22 includes the two or more groove parts GRO as in the second example, the lengths of the first pass area COA12 and the second pass area COA22′ may be further increased, and thus, the mobility of the thin film transistor may be more easily improved.

According to the first and second examples illustrated in FIGS. 6 and 11, an edge of the groove part GRO has a bent shape. However, a shape of the groove part GRO according to one or more embodiments is not limited to those illustrated in FIGS. 6 and 11.

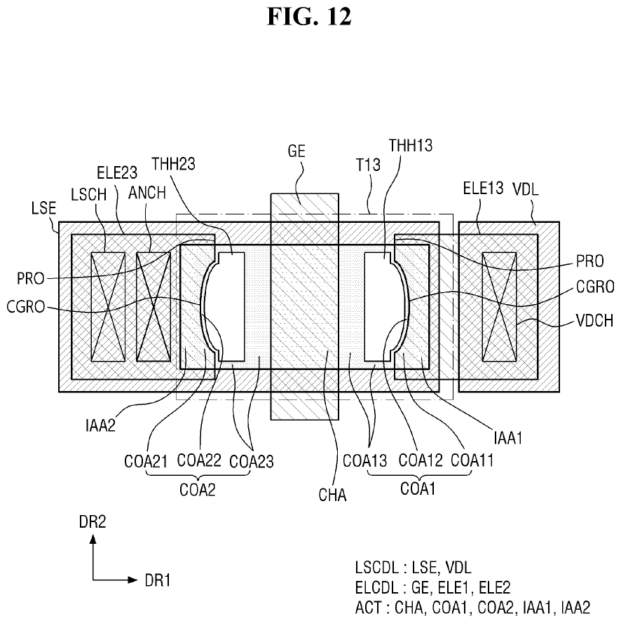

FIG. 12 is a plan view illustrating a third example of a first thin film transistor of the pixel driver of FIG. 5.

Referring to FIG. 12, a first thin film transistor T13 of a third example is substantially the same as that of the first example illustrated in FIGS. 6 to 8 except that the groove part CGRO provided on one side of each of the first electrode ELE13 and the second electrode ELE23 has a curved arc shape, and thus, an overlapping description will hereinafter be omitted.

According to the third example, as the groove part CGRO between the protrusion parts PRO is formed in a curved shape, bent portions are decreased in each of the first pass area COA12 and the second pass area COA22, and thus, current concentration in the bent portions may be reduced. Consequently, current characteristics and heat generation of the thin film transistor T1 may be improved.

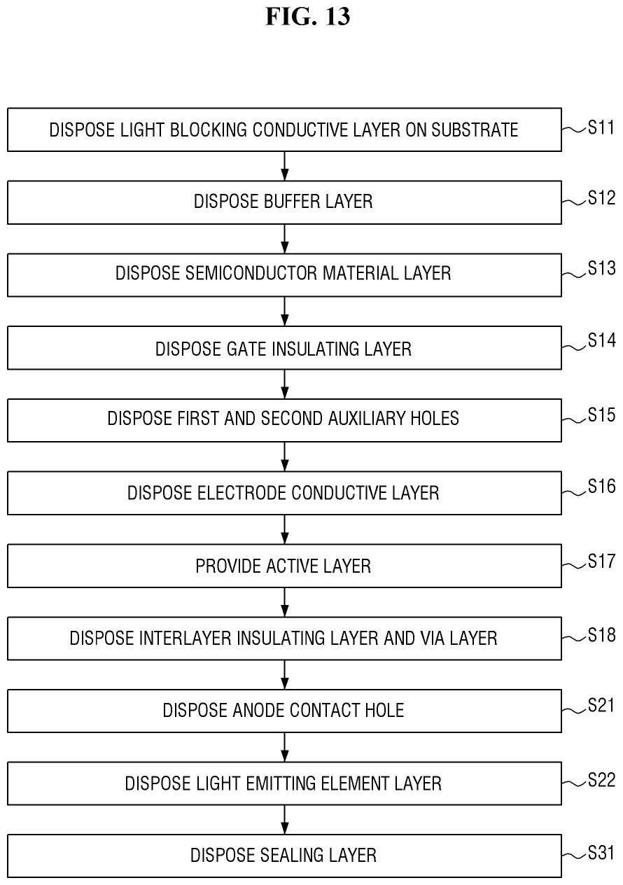

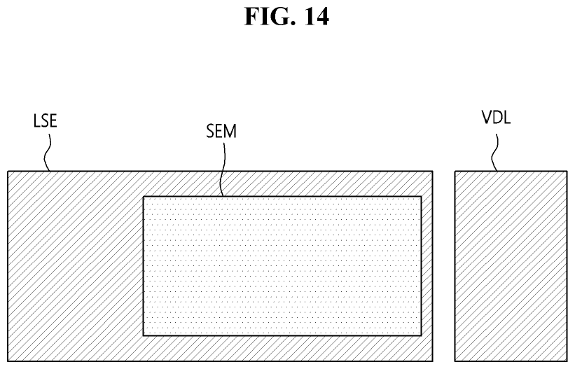

FIG. 13 is a flowchart illustrating a method of manufacturing a transistor array substrate according to one or more embodiments. FIGS. 14 to 26 are views illustrating processes related to respective steps of FIG. 13.

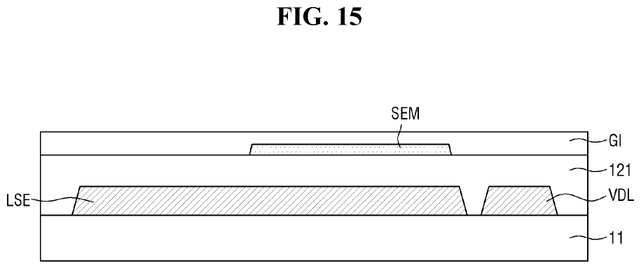

Referring to FIG. 13, a method of manufacturing a transistor array substrate 10 according to one or more embodiments may include disposing the light blocking conductive layer LSCDL on the substrate 11 (S11), disposing the buffer layer 121 covering the light blocking conductive layer LSCDL (S12), disposing a semiconductor material layer SEM (e.g., see FIGS. 14 and 15) on the buffer layer 121 (S13), disposing the gate insulating layer GI covering the semiconductor material layer (SEM) (S14), disposing a first auxiliary hole and a second auxiliary hole penetrating through the gate insulating layer GI (S15), disposing the electrode conductive layer ELCDL on the gate insulating layer GI (S16), providing the active layer ACT including the channel area CHA, the first conductive area COA1, and the second conductive area COA2 by partially removing the gate insulating layer GI (S17), disposing the interlayer insulating layer 122 covering the electrode conductive layer ELCDL and disposing the via layer 123 on the interlayer insulating layer 122 (S18), disposing the anode contact hole ANCH penetrating through the interlayer insulating layer 122 and the via layer 123 (S21), disposing the light emitting element layer 13 on the via layer 123 (S22), and disposing the sealing layer 14 covering the light emitting element layer 13 (S31).

Referring to FIGS. 14 and 15, the light blocking conductive layer LSCDL including the light blocking electrode LSE and the first power line VDL may be disposed by partially removing a conductive layer on the substrate 11 (S11).

The light blocking conductive layer LSCDL may further include the data line DL and the initialization voltage line VIL.

Then, the buffer layer 121 covering the light blocking conductive layer LSCDL including LSE and VDL may be disposed by stacking an insulating material on the substrate 11 (S12).

Then, the semiconductor material layer SEM may be disposed on the buffer layer 121 (S13).

Then, the gate insulating layer GI covering the semiconductor material layer SEM may be disposed by stacking an inorganic insulating material on the buffer layer 121 (S14) and the semiconductor material layer SEM.

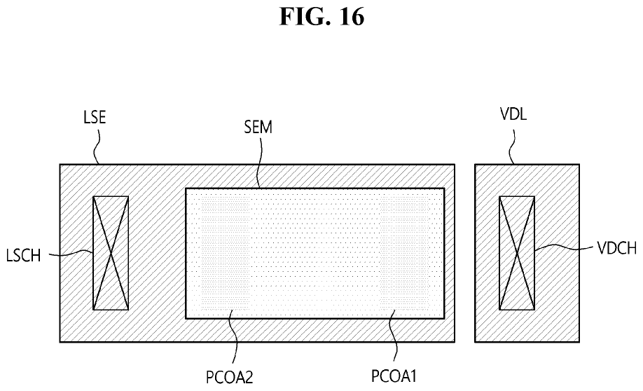

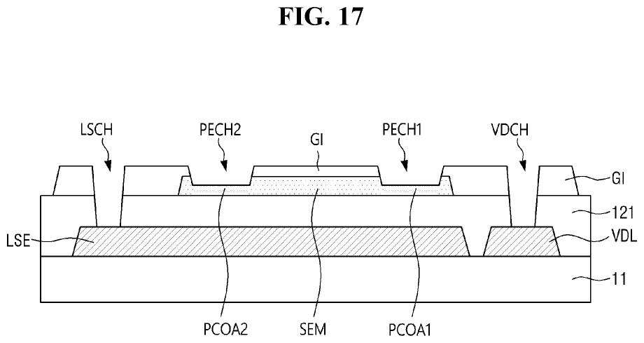

Referring to FIGS. 16 and 17, the power connection hole VDCH and the light blocking connection hole LSCH penetrating through the gate insulating layer GI and the buffer layer 121, and the first auxiliary hole PECH1 and the second auxiliary hole PECH2 penetrating through the gate insulating layer GI may be disposed using a halftone mask (S15).

The power connection hole VDCH may expose a portion of the first power line VDL.

The light blocking connection hole LSCH may expose a portion of the light blocking electrode LSE.

The first auxiliary hole PECH1 and the second auxiliary hole PECH2 may expose different portions of the semiconductor material layer SEM.

A portion of the semiconductor material layer SEM exposed through the first auxiliary hole PECH1 is exposed to an etching process to become conductive, and may thus be provided as a first pre-conductive area PCOA1.

Another portion of the semiconductor material layer SEM exposed through the second auxiliary hole PECH2 is exposed to an etching process to become conductive, and may thus be provided as a second pre-conductive area PCOA2.

In order to secure an etching margin, the first auxiliary hole PECH1 and the second auxiliary hole PECH2 may be spaced from both ends of the semiconductor material layer SEM, respectively.

Accordingly, the first inactive area IAA1 (e.g., see FIG. 6) adjacent to the first auxiliary hole PECH1 may be provided at one end of the semiconductor material layer SEM, and the second non-active area IAA2 (e.g., see FIG. 6) adjacent to the second auxiliary hole PECH2 may be provided at the other end of the semiconductor material layer SEM.

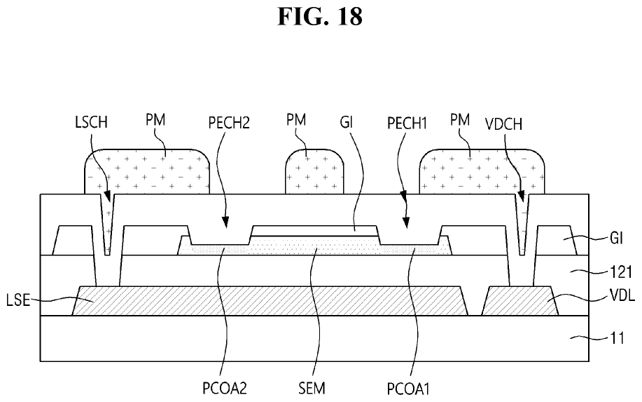

Referring to FIG. 18, a conductive material layer covering the semiconductor material layer SEM and the gate insulating layer GI may be deposited by stacking a conductive material on the buffer layer 121, and a photomask layer PM may be then disposed on the conductive material layer.

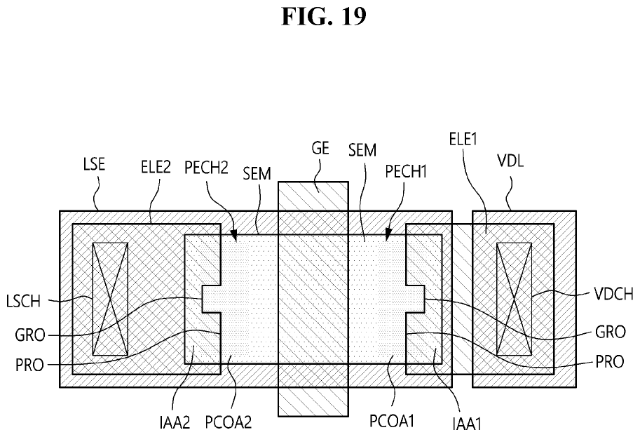

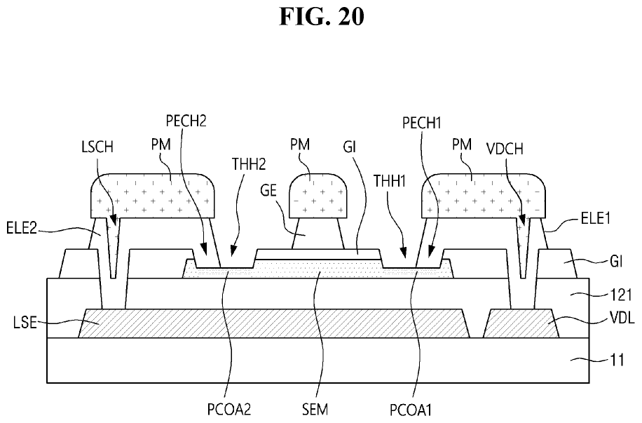

Referring to FIGS. 19 and 20, the electrode conductive layer ELCDL including the gate electrode GE, the first electrode ELE1, and the second electrode ELE2 may be disposed by partially etching the conductive material layer based on the photomask layer PM (S16).

The gate electrode GE overlaps a portion of the semiconductor material layer SEM in the third direction DR3 and is spaced from each of the first pre-conductive area PCOA1 and the second pre-conductive area PCOA2.

The first electrode ELE1 overlaps the power connection hole VDCH and extends to the first pre-conductive area PCOA1 to overlap a portion the first pre-conductive area PCOA1.

The second electrode ELE2 overlaps the light blocking connection hole LSCH and extends to the second pre-conductive area PCOA2 to overlap a portion the second pre-conductive area PCOA2.

As illustrated in FIG. 19, according to one or more embodiments, one side of each of the first and second electrodes ELE1 and ELE2 facing the gate electrode GE includes the protrusion parts PRO and the groove part GRO.

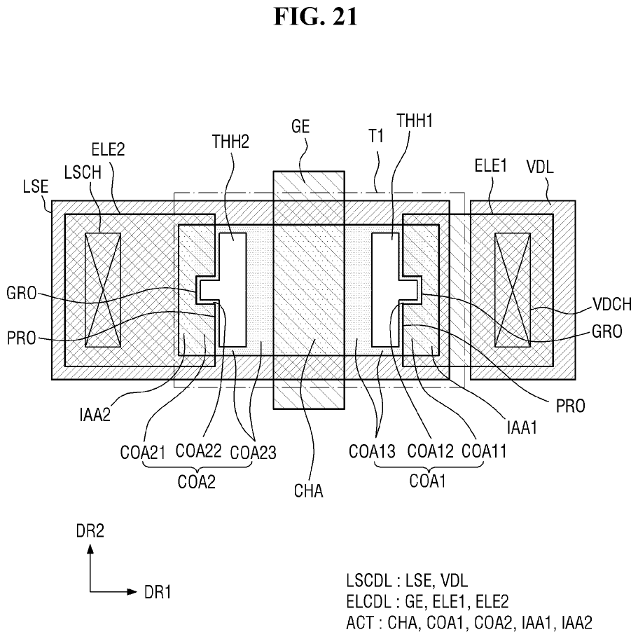

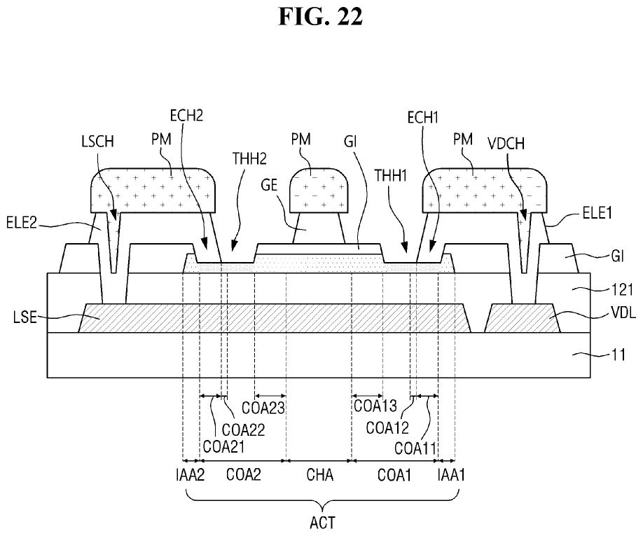

As illustrated in FIGS. 21 and 22, the first auxiliary hole PECH1 may be expanded as the first electrode connection hole ECH1 and the second auxiliary hole PECH2 may be expanded as the second electrode connection hole ECH2 by partially etching the gate insulating layer GI based on the photomask layer PM.

In this case, the first conductive area COA1 and the second conductive area COA2 formed of different portions of the semiconductor material layer SEM may be provided by the first electrode connection hole ECH1 and the second electrode connection hole ECH2, respectively.

Consequently, the active layer ACT including the channel area CHA, the first conductive area COA1, and the second conductive area COA2 may be provided (S17).

The active layer ACT may further include the first non-active area IAA1 connected to the first conductive area COA1, covered with the gate insulating layer GI, and overlapping the first electrode ELE1 in the third direction DR3 and the second inactive area IAA2 connected to the second conductive area COA2, covered with the gate insulating layer GI, and overlapping the second electrode ELE2 in the third direction.

In addition, in a process of partially etching the gate insulating layer GI based on the photomask layer PM (S17), a portion of the first pre-conductive area PCOA1 and a portion of the second pre-conductive area PCOA2 are not covered with the photomask layer PM, and may be exposed to and removed by an etching process. That is, the first through hole THH1 and the second through hole THH2 are generated.

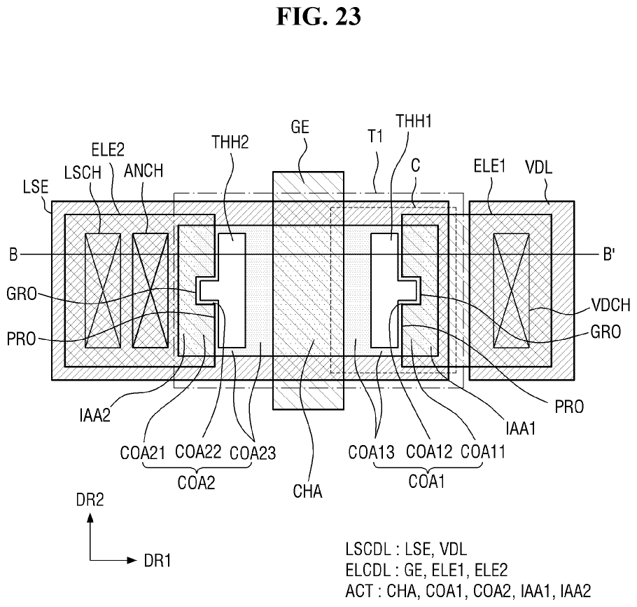

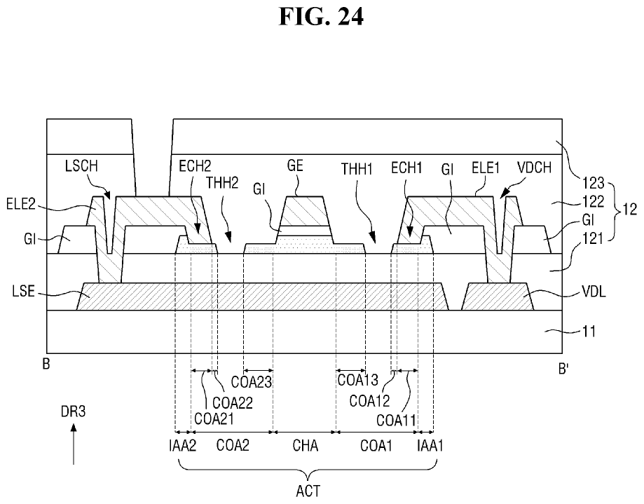

Then, as illustrated in FIGS. 23 and 24, the photomask layer PM may be removed, and the interlayer insulating layer 122 covering the electrode conductive layers ELCDL including GE, ELE1, and ELE2 and the via layer 123 may then be sequentially disposed on the buffer layer 121 (S18).

Then, the anode connection hole ANCH penetrating through the interlayer insulating layer 122 and the via layer 123 and exposing a portion of the second electrode ELE2 of the first thin film transistor T1 may be disposed (S21).

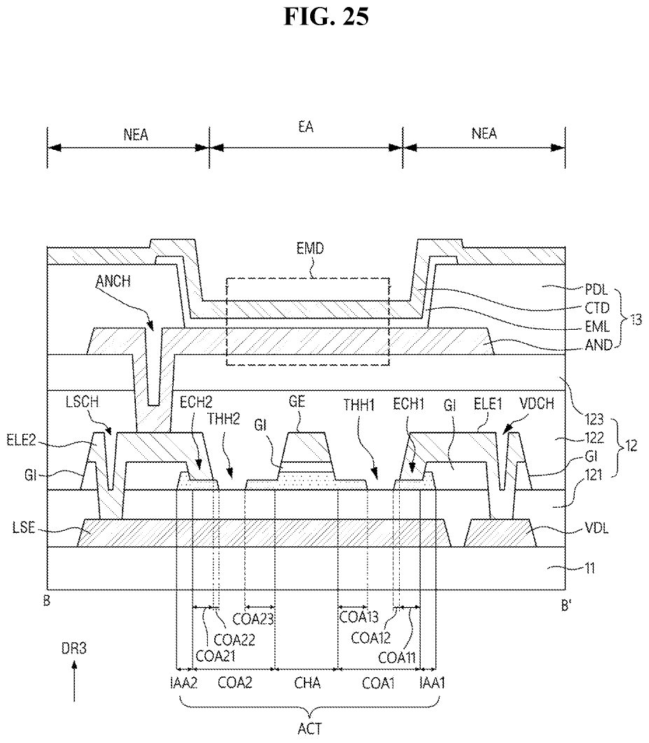

As illustrated in FIG. 25, the light emitting element layer 13 may be disposed on the via layer 123 (S22).

The light emitting element layer 13 may include the anode electrode AND electrically connected to the first thin film transistor T1 through the anode contact hole ANCH, the pixel definition layer PDL disposed at a portion between the anode electrodes AND of the sub-pixels PX spaced from each other, the light emitting layer EML disposed on the anode electrode AND, and the cathode electrode CTD disposed on the light emitting layer EML.

The anode electrode AND may be a pixel electrode corresponding to each of the sub-pixels PX. The anode electrode AND may reflect at least a portion of light generated from the light emitting layer EML.

The cathode electrode CTD may be a common electrode corresponding to the sub-pixels PX as a whole. The cathode electrode CTD may transmit at least a portion of the light generated in the light emitting layer EML therethrough.

The light emitting layer EML may be disposed in each of the sub-pixels PX. Alternatively, when the display device 1 includes a color filter member or a color conversion member or displays a single color, the light emitting layer EML may be equally disposed in the sub-pixels PX as a whole.

Then, the sealing layer 14 may be disposed on the light emitting element layer 13 (S31).

Consequently, the transistor array substrate 10 according to one or more embodiments may be provided.

As described above, the method of manufacturing a transistor array substrate 10 according to one or more embodiments includes disposing the electrode conductive layer ELCDL including the gate electrode GE, the first electrode ELE1, and the second electrode ELE2 (S16), and accordingly, the number of mask processes may be decreased.

In addition, one side of each of the first electrode ELE1 and the second electrode ELE2 facing the gate electrode GE includes the groove part GRO concavely recessed from the gate electrode GE. Therefore, the length of the first pass area COA12 and the length of the second pass area COA22 are increased, such that the resistance of the thin film transistor T1 may be decreased, and accordingly, the current characteristics and the uniformity of the current characteristics of the thin film transistor T1 may be improved.

However, the aspects and features of the present disclosure are not restricted to the one set forth herein. The above and other aspects and features of the present disclosure will become more apparent to one of daily skill in the art to which the present disclosure pertains by referencing the claims, with functional equivalents thereof to be included therein.

What is claimed is:

1. A thin film transistor comprising:
a substrate;
an active layer on the substrate and including a channel area, a first conductive area connected to one side of the channel area, and a second conductive area connected to an other side of the channel area;
a gate insulating layer on a portion of the active layer;
a first through hole penetrating through a portion of the first conductive area;
a second through hole penetrating through a portion of the second conductive area;
a gate electrode in an electrode conductive layer on the gate insulating layer and overlapping the channel area of the active layer;
a first electrode in the electrode conductive layer, adjacent to one side of the first through hole, and electrically connected to the first conductive area; and
a second electrode in the electrode conductive layer, adjacent to one side of the second through hole, and electrically connected to the second conductive area,
wherein one side of the first electrode adjacent to the first through hole is parallel to the one side of the first through hole, the first electrode comprising protrusion parts at both ends thereof and a groove part concavely recessed from the gate electrode as compared with the protrusion parts.

2. The thin film transistor of claim 1, wherein the first conductive area corresponds to a first electrode connection hole penetrating through the gate insulating layer,
wherein the second conductive area corresponds to a second electrode connection hole penetrating through the gate insulating layer,
wherein the first electrode extends to the first conductive area and in contact with a first contact area of the first conductive area, and
wherein the second electrode extends to the second conductive area and in contact with a second contact area of the second conductive area.

3. The thin film transistor of claim 2, wherein a length of a first pass area between the one side of the first through hole and the first contact area in the first conductive area is greater than a width of the one side of the first through hole.

4. The thin film transistor of claim 3, wherein one side of the second electrode adjacent to the second through hole is parallel to the one side of the second through hole, is symmetrical to the first electrode with respect to the gate electrode, the second electrode comprising protrusion parts and a groove part, and
wherein a length of a second pass area between the one side of the second through hole and the second contact area in the second conductive area is greater than a width of the one side of the second through hole.

5. The thin film transistor of claim 4, wherein the first conductive area includes a first main area between the channel area and the first pass area, and
wherein the second conductive area includes a second main area located between the channel area and the second pass area.

6. The thin film transistor of claim 5, wherein in a first direction in which the first electrode and the gate electrode face each other, a maximum width of the first contact area is greater than a width of the groove part.

7. The thin film transistor of claim 6, wherein in the first direction, a difference between the maximum width of the first contact area and the width of the groove part is 0.5 μm or more.

8. The thin film transistor of claim 6, wherein in a second direction crossing the first direction, a width of the first conductive area is greater than a width of the first through hole, and
wherein one side of an edge of the first through hole in the first direction is in contact with the first pass area, and the other side of the edge of the first through hole in the first direction and both sides of the edge of the first through hole in the second direction are in contact with the first main area.

9. The thin film transistor of claim 8, wherein a width of the groove part in the second direction is equal to or less than ½ of a width of the first through hole in the second direction.

10. The thin film transistor of claim 9, wherein the width of the groove part in the second direction is 1 μm or more.

11. The thin film transistor of claim 8, wherein the length of the first pass area corresponds to the width of the first through hole in the second direction and the width of the groove part in the first direction.

12. The thin film transistor of claim 8, wherein the one side of the first electrode further comprises a middle protrusion part between two or more groove parts.

13. The thin film transistor of claim 12, wherein a width of the middle protrusion part in the second direction is 1 μm or more.

14. The thin film transistor of claim 8, wherein the groove part has a curved arc shape, and
wherein the length of the first pass area corresponds to the width of the first through hole in the second direction and an arc length of the groove part.

15. The thin film transistor of claim 2, wherein the active layer further comprises:
a first non-active area connected to the first contact area of the first conductive area and covered with the gate insulating layer; and
a second non-active area connected to the second contact area of the second conductive area and covered with the gate insulating layer.

16. A transistor array substrate comprising:
a substrate including a display area in which sub-pixels are arranged; and
a circuit layer on the substrate and including pixel drivers, each of the pixel drivers corresponding to a sub-pixel of the sub-pixels,
wherein each of the pixel drivers comprises at least one thin film transistor,
wherein the thin film transistor of the circuit layer comprises:
an active layer on the substrate and including a channel area, a first conductive area connected to one side of the channel area, and a second conductive area connected to an other side of the channel area;
a gate insulating layer on a portion of the active layer;
a first through hole penetrating through a portion of the first conductive area;
a second through hole penetrating through a portion of the second conductive area;
a gate electrode in an electrode conductive layer on the gate insulating layer and overlapping the channel area of the active layer;
a first electrode in the electrode conductive layer, adjacent to one side of the first through hole, and electrically connected to the first conductive area; and
a second electrode in the electrode conductive layer, adjacent to one side of the second through hole, and electrically connected to the second conductive area,
wherein one side of the first electrode adjacent to the first through hole is parallel to the one side of the first through hole, the first electrode comprising protrusion parts at both ends thereof and a groove part concavely recessed from the gate electrode as compared with the protrusion parts.

17. The transistor array substrate of claim 16, wherein the first conductive area corresponds to a first electrode connection hole penetrating through the gate insulating layer,
wherein the second conductive area corresponds to a second electrode connection hole penetrating through the gate insulating layer,
wherein the first electrode extends to the first conductive area and contacts a first contact area of the first conductive area,
wherein the second electrode extends to the second conductive area and contacts a second contact area of the second conductive area,
wherein a length of a first pass area between the one side of the first through hole and the first contact area in the first conductive area is greater than a width of the one side of the first through hole,
wherein one side of the second electrode adjacent to the second through hole is parallel to the one side of the second through hole, is symmetrical to the first electrode with respect to the gate electrode, and comprises protrusion parts and a groove part, and
wherein a length of a second pass area between the one side of the second through hole and the second contact area in the second conductive area is greater than a width of the one side of the second through hole.

18. The transistor array substrate of claim 17, wherein the first conductive area includes a first main area between the channel area and the first pass area,
wherein in a first direction in which the first electrode and the gate electrode face each other, a maximum width of the first contact area is greater than a width of the groove part,
wherein in a second direction crossing the first direction, a width of the first conductive area is greater than a width of the first through hole, and
wherein one side of an edge of the first through hole in the first direction is in contact with the first pass area, and the other side of the edge of the first through hole in the first direction and both sides of the edge of the first through hole in the second direction are in contact with the first main area.

19. The transistor array substrate of claim 18, wherein the length of the first pass area corresponds to the width of the first through hole in the second direction and the width of the groove part in the first direction.

20. The transistor array substrate of claim 17, wherein the active layer further includes:
a first non-active area connected to the first contact area of the first conductive area and covered with the gate insulating layer; and
a second non-active area connected to the second contact area of the second conductive area and covered with the gate insulating layer.

21. The transistor array substrate of claim 17, further comprising a light emitting element layer on a via layer of the circuit layer,
wherein the light emitting element layer comprises light emitting elements electrically connected to respective pixel drivers through anode contact holes penetrating through the via layer and an interlayer insulating layer,
wherein the circuit layer further comprises:
scan gate lines to transfer scan signals to the pixel drivers;
data lines to transfer data signals to the pixel drivers; and
initialization voltage lines to transfer initialization voltages to the pixel drivers, and
wherein a pixel driver from among the pixel drivers comprises:
a first thin film transistor connected to a light emitting element from among the light emitting elements connected in series between a first power line and a second power line, the first and second power lines to transfer a first power and a second power for driving the light emitting elements;
a second thin film transistor electrically connected between the data line and a gate electrode of the first thin film transistor and is configured to turn on based on a scan signal of the scan gate line;
a pixel capacitor electrically connected to a first node between the gate electrode of the first thin film transistor and the second thin film transistor and a second node between the first thin film transistor and the light emitting element; and
a third thin film transistor electrically connected between the initialization voltage line and the second node and is configured to turn on based on an initialization control signal of an initialization gate line.

22. The transistor array substrate of claim 17, wherein the circuit layer further comprises:
a light blocking electrode in a light blocking conductive layer on the substrate and overlapping the active layer;
a buffer layer on the substrate and covering the light blocking conductive layer;
an interlayer insulating layer on the buffer layer and covering the thin film transistor;
a via layer on the interlayer insulating layer, and
the interlayer insulating layer is in contact with the buffer layer through each of the first through hole and the second through hole.

23. The transistor array substrate of claim 22, wherein the first power line is in the light blocking conductive layer,
wherein a first electrode of the first thin film transistor is electrically connected to the first power line through a power connection hole penetrating through the gate insulating layer and the buffer layer, and
wherein a second electrode of the first thin film transistor is electrically connected to the light blocking electrode through a light blocking connection hole penetrating through the gate insulating layer and the buffer layer.
